(19) United States
(12) Patent Application Publication
(10) Pub. No.: US 2013/0092230 A1
(43) Pub. Date: Apr. 18, 2013

(54) SUBSTRATE COMPRISING A TRANSPARENT CONDUCTIVE OXIDE FILM AND ITS MANUFACTURING PROCESS

(71) Applicants: Alexandre Pereira, Saint Martin le Vinoux (FR); Cedric Ducros, Bevenais (FR); Zoe Tebby, Le Grand Pressigny (FR)

(72) Inventors: Alexandre Pereira, Saint Martin le Vinoux (FR); Cedric Ducros, Bevenais (FR); Zoe Tebby, Le Grand Pressigny (FR)

(73) Assignee: COMMISSARIAT A L'ENERGIE ATOMIQUE ET AUX ENERGIES ALTERNATIVES, Paris (FR)

(21) Appl. No.: 13/806,573

(22) PCT Filed: Jun. 22, 2011
(86) PCT No.: PCT/IB2011/052738

§ 371 Date: Dec. 21, 2012

(30) Foreign Application Priority Data
Jun. 23, 2010 (FR) 1002626

(51) Int. Cl. B05D 5/12; H01L 21/768; H01L 31/0224; H01L 23/482

(52) U.S. Cl. CPC B05D 5/12; H01L 23/4827; H01L 21/76838; H01L 31/022466
USPC 136/256; 427/126.3; 257/749; 438/609; 428/148; 428/149; 428/143

(57) ABSTRACT

The invention relates to a substrate comprising at least one scattering film made of a transparent conductive oxide (TCO) and to a process for manufacturing such a substrate. It also relates to a solar cell comprising such a substrate. The substrate according to the invention comprises a layer of spherical particles made of a material chosen from dielectric and transparent conductive oxides, the layer being coated with a TCO film and the diameters of said spherical particles belonging to at least two populations of different diameters. The invention is applicable in particular to solar cells.

The invention relates to a substrate comprising at least one scattering layer made of a transparent conductive oxide (TCO), and to a process for manufacturing such a substrate.

It also relates to a solar cell comprising such a substrate.

Developing ways to deposit transparent conductive oxides (TCOs) having optimal electrical and optical properties, i.e. typically a transmission higher than 90% in the wavelength range between 350 and 1100 nm and a resistivity lower than 5×10⁻⁴ Ω·cm, is a subject of great interest with respect to improving the performance of thin-film solar cells. These solar cells are cells based on hydrogenated amorphous silicon (a-Si:H), tandem cells, cells based on an absorber layer made of Cu(In,Ga)Se₂ (CIGS), etc.

In these solar cells, the surface texturing of the TCOs is used to improve the scattering of photons toward the active material of the solar cell (optical trapping), and thus increase the photoelectric conversion efficiency.

The optical response of a textured transparent conductive oxide is, in general, quantified by its “haze value”, i.e. its light scattering factor.

This quantity is the ratio of the scattered light transmitted to the total amount of light transmitted.

In order to improve the scattering of photons toward the active material of the solar cell, and thus increase the photoelectric conversion efficiency, it is known to “texturize” the surface of the transparent oxide layer via which the incident light penetrates into the solar cell. This “texturing” corresponds to the roughness created, i.e. a series of recesses and protrusions created on the surface of the TCO layer.

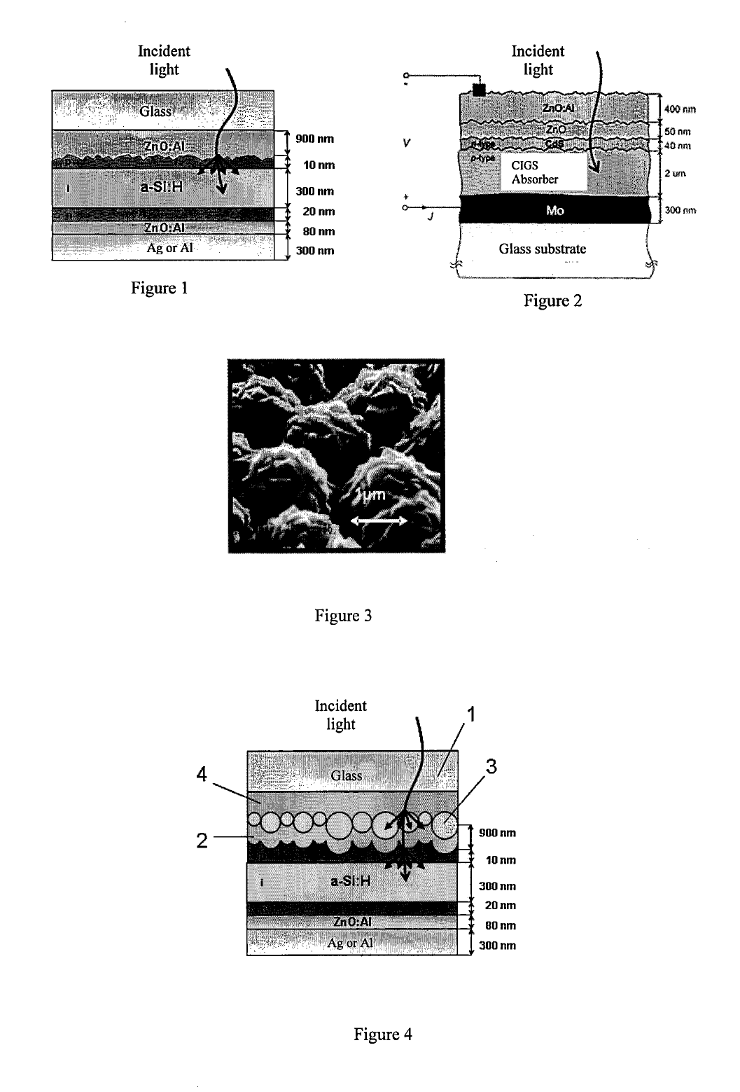

FIG. 1 schematically shows an a-Si:H solar cell with a superstrate configuration, i.e. in which light enters through the glass substrate, and FIG. 2 schematically shows the structure of a CIGS cell with a substrate configuration.

As may be seen, in these structures the thickness of the TCO layer typically varies from 200 nm to 1 μm.

In these configurations, the TCO layer, the function of which is to transmit light, serves as a charge-collecting electrode and, by way of its “texturing”, scatters light.

At the present time, Asahi® U glass, consisting of a glass substrate coated with an SnO₂:F layer deposited by APCVD, sets the standard in the field of a-Si:H solar cells.

The textured TCO layer is produced by atmospheric pressure chemical vapor deposition (APCVD) at a temperature between 200 and 600° C., so as to obtain the “texturing”.

In general, the TCO is fluorine-doped tin oxide (SnO₂:F).

This glass is manufactured using a process described in European patent application No. 1 443 527 A1.

This process consists in depositing, on a glass substrate, a film of transparent conductive oxide, by atmospheric pressure chemical vapor deposition, at a temperature of 500° C., with simultaneous injection of tin tetrachloride, water, and gaseous hydrogen chloride. Using this process, discontinuous protrusions are formed on the surface of the glass substrate.

Next, a continuous transparent conductive oxide layer is formed on these discontinuous protrusions, using an atmospheric pressure chemical vapor deposition method. This layer may also be produced by electron-beam vapor deposition, a vacuum vapor deposition method, a spraying method or a sputtering method.

In the case of APCVD, the surface is “textured” with the recesses and protrusions formed during the deposition of the first oxide layer, as may be seen in FIG. 3, which is a scanning electron micrograph of the surface of Asahi® HU glass.

However, in this process, the recesses and protrusions formed, independently of their texturing, are all of the same size and the obtained glass have a diffuse light transmission higher than 80% only in the wavelength range centered around 350 to 400 nm.

In addition, these diffuse transmission values very rapidly decrease below 80% from 550 nm upwards.

Besides, J. Zhu et al. described, in “Nanodome Solar Cells with Efficient Light Management and Self-Cleaning” Nanoletters 2009, a technique for structuring a complete a-Si:H solar-cell multilayer by texturing the substrate with nanodomes. These nanodomes are produced by plasma etching silica beads deposited beforehand on the substrate.

The etching of these beads results in a periodic array of nanodomes. This periodic array is then reproduced in the entire cell via deposition of a multilayer. However, this process comprises many steps, including a step of etching silica beads. Introducing additional steps into a manufacturing process leads to a non-negligible cost increase.

The invention aims to overcome the problems of processes for forming substrates comprising one or more scattering layers made of transparent conductive oxides, by providing a substrate comprising at least one transparent conductive oxide scattering layer, and a process for manufacturing it, enabling a scattering factor or haze value higher than 80% to be obtained over all of the wavelengths between 350 and 1500 nm inclusive, the process requiring only few manufacturing steps.

For this purpose, the invention relates to a substrate comprising at least a first scattering layer made of a transparent conductive oxide (TCO) deposited on at least one surface of a support, noteworthy in that in addition it comprises a layer of spherical particles made of a material chosen from dielectric materials and transparent conductive oxides, and the diameters of which belong to at least two populations of different diameters, under the layer made of TCO, the layer made of TCO having a substantially constant thickness, i.e. being a conformal deposition.

The expression “substantially constant thickness” is understood to mean that the thickness differs by no more than 20% and preferably no more than 10% about, above or below, the average thickness of the layer.

The expression “two populations of different diameters” is in particular understood to mean that, in the total population of spherical particles forming the layer 3, at least 5% by number of said particles have a diameter larger or smaller, by more than 500 nm, than the diameter of at least 5% by number of the spherical particles, relative to the total number of spherical particles.

Preferably, the substrate of the invention in addition comprises, between the support and the layer of spherical particles, a second layer made of a transparent conductive oxide that is identical to, or different from, that forming the first TCO layer.

Advantageously, the first and second TCO layers coat the layer of spherical particles, so that said particles make continuous contact with the TCO layers.

The support of the substrate of the invention is made of a material chosen from glass, p-doped silicon, n-doped silicon, hydrogenated amorphous silicon (a-Si:H), Cu(In,Ga)Se₂, single-crystal silicon or polysilicon, CdS, or a layer of an organic cell.

In the layer of spherical particles employed in the invention, the particles do not systematically make contact with one another. Preferably, they only make partial contact.

The spherical particles preferably have an average diameter of between 300 nm and 10 μm inclusive. This diameter may be measured by transmission electron microscopy.

According to one preferred embodiment, in the total population of spherical particles forming the layer 3, at least 15%, by number, of said particles have a diameter larger or smaller by more than 500 nm than the diameter of at least 15%, by number, of 100%, by number, of the spherical particles.

In another preferred embodiment, at least 10% and preferably 15%, by number, of the entire population of spherical particles has a diameter of between 200 nm and 4 μm inclusive, and at least 10% and preferably 15%, by number, of the entire population of spherical particles has a diameter of between 4.5 μm and 12 μm inclusive, the rest of the particles having intermediate diameters.

In this case, more preferably, among the population the diameter of which lies between 200 nm and 4 μm inclusive, at least 5%, by number, of the particles, relative to the total number of particles, have a diameter of between 300 nm and 3.5 μm inclusive, and among the population having a diameter of between 4.5 μm and 12 μm inclusive, 5%, by number, relative to the total number of particles, all the populations taken together, have a diameter larger than 4.5 μm and smaller than 6 μm.

The spherical particles are made of a material chosen from SiO₂, SnO₂, ZnO, ZnO:Al, ZnO:B, SnO₂:F, ITO, fluorine-doped indium oxide, In₂O₃:Mo (IMO), and ZnO:Ga.

As regards the transparent conductive oxide, it is chosen from ZnO:Al (AZO), ZnO:B (BZO), ZnO:Ga (GZO), SnO₂:F, In₂O₃:Sn (ITO), ITO:ZnO, ITO:Ti, In₂O₃, In₂O₃:ZnO (IZO), In₂O₃:F, In₂O₃:Mo (IMO), In₂O₃:Ga, In₂O₃:Ti, In₂O₃:W, In₂O₃:Zr, In₂O₃:Nb, ZnO:(Al,F), and ZnO:(Ga,B).

The invention also provides a process for manufacturing a substrate comprising at least one scattering layer made of a transparent conductive oxide (TCO), characterized in that it comprises the following steps:

a) depositing, on at least one surface of a support, a layer of spherical particles of a material chosen from dielectric materials and transparent conductive oxides, the diameters of which belong to at least two populations of different diameters; and

b) depositing, on the free surface of the layer of spherical particles a layer made of a conformal transparent conductive oxide.

In a preferred embodiment, the process of the invention in addition comprises, before step a), a step of depositing, on the layer of spherical particles deposited on the support, a second layer made of a transparent conductive oxide that is identical to, or different from, the transparent conductive oxide forming the first TCO layer, that surface of this layer which makes contact with the layer having the same shape as the surface formed by the layer with which it makes contact.

According to a first variant, the one or more layers of transparent conductive oxide are deposited by physical vapor deposition (PVD).

Preferably, and according to a second variant, the one or more layers of transparent conductive oxide are deposited by chemical vapor deposition (CVD).

In all the variants of the process of the invention, the support is made of a material chosen from glass, p-doped silicon, n-doped silicon, hydrogenated amorphous silicon (a-Si:H), Cu(InGa)Se₂, single-crystal silicon or polysilicon, CdS, or a layer of an organic cell.

Also preferably, the spherical particles have a diameter of between 300 nm and 10 μm inclusive.

Most preferably, at least 10% and preferably 15%, by number, of the total population of spherical particles has a diameter of between 200 nm and 4 μm inclusive, and at least 10% and preferably 15%, by number, of the total population of spherical particles has a diameter of between 4.5 μm and 12 μm inclusive, the rest of the population consisting of particles of intermediate diameter.

In addition, preferably, the spherical particles are made of a material chosen from SiO₂, ZnO, ZnO:Al, ZnO:B, SO₂:F, ITO, fluorine-doped indium oxide, In₂O₃:Mo (IMO), and ZnO:Ga.

As regards the transparent conductive oxide, it is preferably chosen from ZnO:Al (AZO), ZnO:B (BZO), ZnO:Ga (GZO), SnO₂:F, In₂O₃:Sn (ITO), ITO:ZnO, ITO:Ti, In₂O₃, In₂O₃:ZnO (IZO), In₂O₃:F, In₂O₃:Mo (IMO), In₂O₃:Ga, In₂O₃:Ti, In₂O₃:W, In₂O₃:Zr, In₂O₃:Nb, ZnO: (Al,F), and ZnO:(Ga,B).

The invention also relates to a solar cell comprising a substrate according to the invention or obtained by the process according to the invention.

The invention will be better understood and other of its features and advantages will become more clearly apparent on reading the following explanatory description, given with reference to the appended figures, in which:

FIG. 1 shows the configuration of a prior-art a-Si:H solar cell, in the superstrate configuration;

FIG. 2 shows a schematic of the structure of a prior-art CIGS solar cell, in the substrate configuration;

FIG. 3 is a scanning electron micrograph of the surface of the transparent conductive oxide layer obtained by the process described in European patent application 1 443 527 A, and sold under the tradename HU by Asahi®;

FIG. 4 shows a schematic of the structure of an a-Si:H solar cell according to the invention in the superstrate configuration;

FIG. 5 shows a schematic of the structure of a CIGS solar cell according to the invention in the substrate configuration;

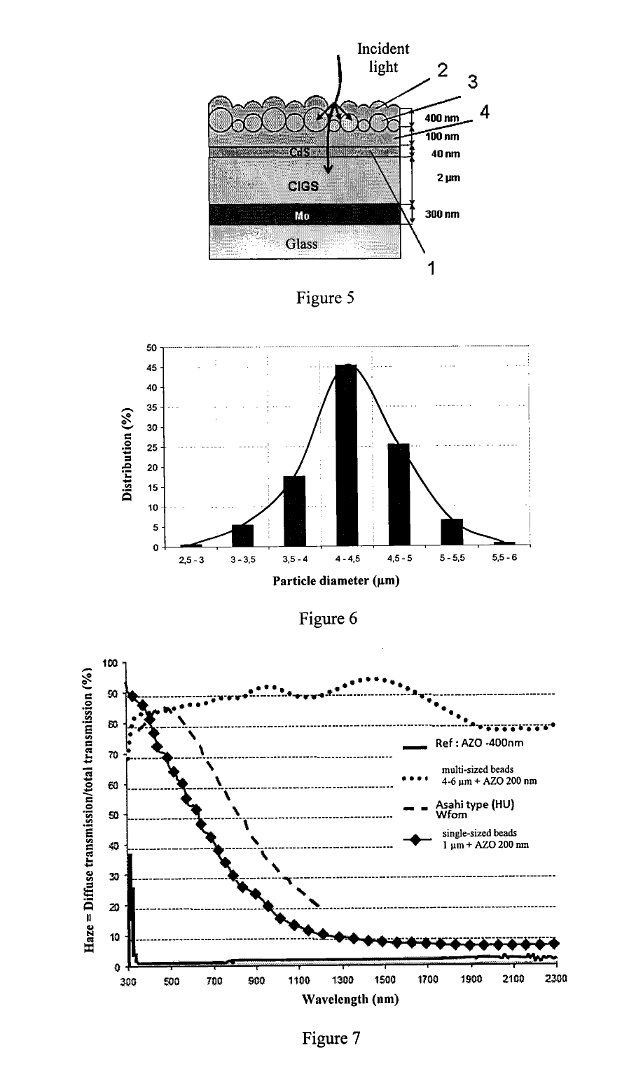

FIG. 6 shows the particle size distribution of the silica beads used in example 1; and

FIG. 7 shows the haze factor as a function of the wavelength of incident light, obtained:
with a substrate according to the invention with either single-sized or multi-sized beads;
the HU type Asahi® substrate; and
a substrate comprising a texture-free transparent conductive oxide layer.

The optical response of a textured transparent conductive oxide layer is in general quantified by its haze value, i.e. the scattering factor of the light.

This quantity is the ratio of the scattered light transmitted to the total amount of light transmitted.

It has been widely demonstrated that this quantity is improved when the transparent conductive oxide (TCO) layer is textured.

In the following, the term “texturing” is understood to mean the roughness created, i.e. the succession of recesses and protrusions formed in or by the TCO layer.

As may be seen in FIGS. 4 and 5, the substrate according to the invention comprises at least one scattering layer made of a transparent conductive oxide, referenced 2 in FIGS. 4 and 5, on a support, referenced 1 in FIGS. 4 and 5, as in the deposited substrates of the prior art shown in FIGS. 1, 2 and 3. However, unlike the substrates of the prior art shown in FIGS. 1, 2 and 3, the substrate of the invention in addition comprises a layer, referenced 3 in FIGS. 4 and 5, of spherical particles made of a material chosen from dielectric materials and transparent conductive oxides.

Specifically, spherical particles made of a material such as, for example, SiO₂, ZnO, indium-doped tin oxide, are deposited between the support 1 and the layer 2. The size of these spherical particles is grouped in at least two populations of diameters.

In other words, the spherical particles forming the layer 3 do not all have the same diameter.

By virtue of the variable size of these particles, the efficiency with which scattered light is transmitted is optimized over a wide wavelength range, i.e. from 350 nm to 1500 nm.

The size of these particles varies between 300 nm and 10 μm. Thus protrusions and recesses of different heights and widths are obtained, which was not possible with the process of European patent application 1 443 527 A1. It is of course possible to select the sizes (diameters) of the dielectric particles in order to select a precise wavelength range.

In a preferred embodiment, and to obtain optimal efficiency over a wide wavelength range between 350 nm and 1500 nm, at least 10% and preferably 15%, by number, of the total population of spherical particles used will have a diameter of between 200 nm and 4 μm inclusive, and at least 10% and preferably 15%, by number, of the total population of spherical particles used will have a diameter of between 4.5 μm and 12 μm inclusive, the rest consisting of particles of intermediate diameters.

According to an improvement of the invention, among the aforementioned 15%, at least 5% by number (relative to the total population) have a diameter of between 300 nm and 3.5 μm inclusive, and 5% by number (relative to the total population) have a diameter of between 4.5 μm and μm inclusive.

In order to further improve the diffuse transmission efficiency, and in a particularly preferred embodiment, the spherical particles do not all make contact with one another, and preferably, they are all separated from one another.

This means, as may be seen in FIGS. 4 and 5, that these spherical particles form a monolayer, i.e. the spherical particles are not stacked on top of one another.

The spherical particles are preferably deposited by Langmuir-Blodgett type deposition, which has the advantage of allowing large areas to be treated inexpensively, or even by spin-coating, dip-coating with a sol-gel, thereby precisely controlling the size and area density of the spherical particles. Liquid polymer/spherical particle nanocomposites are preferably used the particle concentration of which determines the final density on the surface of the treated substrate. The polymer solvent is then evaporated by a heat treatment. A surfactant may be used in order to promote a good dispersion of the particles.

This layer 3 of spherical particles is then coated with the transparent conductive oxide layer.

As may be seen in FIGS. 4 and 5, the shape of the transparent conductive oxide layer 2 is a negative of the surface of the layer 3 of spherical particles. It has the same thickness at every point. It is a conformal deposition.

By way of transparent conductive oxide, use may be made of any transparent conductive oxide known to those skilled in the art. By way of example, mention may be made of ZnO:Al, indium-doped tin oxide (ITO), molybdenum-doped tin oxide (IMO), undoped or fluorine-doped SnO₂ (SnO₂:F), SnO₂, ZnO:B, SnO₂:F, ITO, fluorine-doped indium oxide, In₂O₃:Mo (IMO), ZnO:Ga.

In a preferred variant of the invention, the device of the invention in addition comprises, between the substrate 1 and the layer 3 of spherical particles, a second layer, referenced 4 in FIGS. 4 and 5, made of a transparent conductive oxide that is identical to that of the layer 2, or different therefrom.

The transparent conductive oxide of the layer 4 is chosen from the same materials as those mentioned regarding the layer 2.

The transparent conductive oxide used to form the layer 2 or the layer 4 may be deposited by physical vapor deposition (PVD) or by chemical vapor deposition (CVD).

These techniques allow the spherical particles made of a dielectric material to be encased in a thin TCO film. The spherical particles are coated.

When the deposition is carried out by PVD, the surface of the recesses and protrusions in the TCO layer 2 and/or 4 has no “texturing”, i.e. it is perfectly smooth.

However, to obtain a TCO layer 2 that perfectly matches the shape of the spherical particles, at the surface that they form, and having the same thickness at every point, it is preferable to use the CVD method. In this case, since the surface of the recesses and protrusions match the shape of the layer 3 of spherical particles, they will themselves have a roughness (texturing).

The process for manufacturing the substrate of the invention comprises the following steps:

a) depositing, on at least one surface of a support 1, a layer 3 of spherical particles of a material chosen from dielectric materials and transparent conductive oxides, and the diameters of which belong to at least two populations of different diameters; and

b) depositing, on the free surface of the layer 3 a layer made of a transparent conductive oxide.

In a preferred embodiment, the process of the invention in addition comprises, before step a), a step of depositing the layer 4 made of a transparent conductive oxide that is identical to, or different from, that forming the layer 2.

The methods used to deposit the layers 2 and/or 4 and the spherical particles have already been described above and the nature of the materials forming the layers 2 and/or 4 and 3 has also already been described above.

The size of the spherical particles was also described above.

The substrate of the invention or obtained by the process of the invention is particularly suited to forming a scattering layer made of TCO for a solar cell.

Thus, another subject of the invention is a solar cell comprising such a substrate.

In order to better understand the invention, embodiments thereof will now be described by way of purely illustrative and nonlimiting examples.

### EXAMPLE 1

Production of a scattering layer made of TCO based on spherical silica particles: production of a substrate according to the invention.

In a first step, a 100 nm-thick layer of ZnO doped with 2.5 wt% aluminum was deposited on a glass support by magnetron sputtering.

Next, spherical silica particles, the particle size distribution of which is shown in FIG. 6, were deposited using a Langmuir-Blodgett process.

Next, the layer of spherical particles was covered with a layer of ZnO doped with 2.5% Al, deposited by magnetron sputtering. This layer was 400 nm in thickness.

### EXAMPLE 2

In this example the first layer of ZnO doped with 2.5% Al was deposited using a magnetron sputtering technique.

The deposition parameters used are given immediately below.

| Target | ZnO:A1 (2.5 wt %) |
|---|---|
| Target diameter | 200 mm |
| Substrate | Eagle XG glass |
| Pressure | 0.15 Pa |
| Ar flow rate | 20 sccm |
| Movement | Rotation - 10 rpm |
| Power | 500 W |
| Power density | 1.6 W/cm² |
| Target-substrate distance | 55 mm |
| Time | 38 min |
| Deposition rate | 100 nm/min |

Next, single-sized silica particles 1 μm in diameter were deposited.

These particles were deposited using a Langmuir-Blodgett technique.

Next a conformal 200 nm-thick second layer of ZnO doped with 2.5% Al was deposited on the monolayer of silica particles so as to cover it entirely.

This deposition was carried out by magnetron sputtering. The parameters used during this deposition were identical to those used in example 1.

### Results

Next, the haze factor was measured, by spectrophotometry, for incident light passing through the substrate obtained in example 1; and, for comparison, the haze factor obtained with the Asahi® HU structure, and with a structure comprising only a “texturing”-free layer of ZnO doped with 2.5% aluminum deposited directly on the glass substrate, and with a structure according to the invention but for which the spherical particles were single sized, such as obtained in example 2, was measured.

The curves obtained are shown in FIG. 7.

As may be seen in FIG. 7, the structure formed only by the ZnO layer doped with 2.5% Al on the glass had no haze factor. This was the reference structure.

As for the Asahi® HU structure, it will be observed that it had a haze factor greater than 80% only in the wavelength range between 350 and 550 nm, with a maximum at 500 nm.

Equivalently, the use of single-sized spheres did not improve the haze factor.

In contrast, with the substrate according to the invention, the haze factor was greater than 80% over a wide wavelength range between 310 and 2300 nm.

1. A substrate comprising:
a first TCO scattering layer of a transparent conductive oxide deposited on a surface of a support,
a layer of spherical particles of a material selected from the group consisting of a dielectric material and a transparent conductive oxide,
wherein
the spherical particles have at least two populations of different diameters,
the layer of spherical particles is positioned under the first TCO scattering layer, and
the first TCO scattering layer has a substantially constant thickness.

2. The substrate as of claim 1, further comprising, between the support and the layer of spherical particles, a second TCO layer of a transparent conductive oxide that is identical to, or different from, the transparent conductive oxide forming the first TCO scattering layer.

3. The substrate of claim 2, wherein the first and second TCO layers coat the layer of spherical particles.

4. The substrate as of claim 1, wherein the support is made of a material selected from the group consisting of a glass, a p-doped silicon, a n-doped silicon, a hydrogenated amorphous silicon (a-Si:H), a Cu(In, Ga)Se₂, a single-crystal silicon or polysilicon, a CdS, and a layer of an organic cell.

5. The substrate of claim 1, wherein the spherical particles have a diameter of between 300 nm and 10 μm inclusive.

6. The substrate of claim 1, characterized in that wherein the layer of spherical particles comprises a first population of spherical particles having at least 5% by number of the spherical particles,
a second population of spherical particles having at least 5% by number of the spherical particles, and
the first population having a diameter larger or smaller by more than 500 nm than the second population.

7. The substrate of claim 1, wherein the spherical particles are made of a material selected from the group consisting of a SiO₂, a ZnO, a ZnO:Al, a ZnO:B, a SnO₂:F, a ITO, a fluorine-doped indium oxide, a In₂O₃:Mo, and a ZnO:Ga.

8. The substrate of claim 1, wherein the transparent conductive oxide is selected from the group consisting of a ZnO:Al, a ZnO:B, a ZnO:Ga, a SnO₂:F, a In₂O₃:Sn, a ITO:ZnO, ITO:Ti, a In₂O₃, a In₂O₃:ZnO, a In₂O₃:F, a In₂O₃:Mo, a In₂O₃:Ga, a In₂O₃:Ti, a In₂O₃:W, a In₂O₃:Zr, a In₂O₃:Nb, a ZnO:(Al,F), and a ZnO:(Ga,B).

9. A process for manufacturing a substrate, the process comprising:
a) depositing, on at least one surface of a support, a layer of spherical particles of a material selected from the group consisting of a dielectric material and a transparent conductive oxide, wherein the spherical particles have at least two populations of different diameters; and
b) depositing a first TCO scattering layer of a transparent conductive oxide on a free surface of the layer of spherical particles, wherein the first TCO scattering layer has a substantially constant thickness.

10. The process of claim 9, further comprising, before depositing a), depositing a second TCO layer made of a transparent conductive oxide that is identical to, or different from, the transparent conductive oxide forming the first TCO scattering layer,
wherein
the second TCO layer is deposited between the substrate and the layer of spherical particles, and
contacting surfaces of the second TCO layer and the layer of spherical particles have a same shape.

11. The process of claim 10, wherein one or both of the first and second TCO layers are deposited by physical vapor deposition.

12. The process of claim 10, wherein one or both of the first and second TCO layers are deposited by chemical vapor deposition.

13. The process of claim 9, wherein the support is made of a material selected from the group consisting of a glass, a p-doped silicon, a n-doped silicon, a hydrogenated amorphous silicon (a-Si:H), a Cu(InGa)Se₂, a single-crystal silicon or polysilicon, a CdS, and a layer of an organic cell.

14. The process as of claim 9, wherein the spherical particles have a diameter of between 300 nm and 10 μm inclusive.

15. The process of claim 9, wherein at least 10% by number of a total population of the spherical particles has a diameter of between 200 nm and 4 μm inclusive, and at least 10% by number of the total population of the spherical particles has a diameter of between 4.5 μm and 12 μm inclusive, with a remaining population having particles of an intermediate diameter.

16. The process of claim 9, wherein the spherical particles are made of a material selected from the group consisting of a SiO₂, a ZnO, a ZnO:Al, a ZnO:B, a SO₂:F, a ITO, a fluorine-doped indium oxide, a In₂O₃:Mo, and a ZnO:Ga.

17. The process of claim 9, wherein the transparent conductive oxide is chosen selected from the group consisting of a ZnO:Al, a ZnO:B, a ZnO:Ga, a SnO₂:F, a In₂O₃:Sn, a ITO:ZnO, a ITO:Ti, a In₂O₃, a In₂O₃:ZnO, a In₂O₃:F, a In₂O₃:Mo, a In₂O₃:Ga, a In₂O₃:Ti, a In₂O₃:W, a In₂O₃:Zr, a In₂O₃:Nb, a ZnO:(Al,F), and a ZnO:(Ga,B).

18. A solar cell, comprising a substrate of claim 1.

19. A solar cell, comprising a substrate obtained by the process of claim 9.

20. The process of claim 9, wherein at least 15% by number of a total population of the spherical particles has a diameter of between 200 nm and 4 μm inclusive, and at least 15% by number of the total population of the spherical particles has a diameter of between 4.5 μm and 12 μm inclusive, with a remaining population having particles of an intermediate diameter.
